(19) United States
(12) Patent Application Publication
(10) Pub. No.: US 2004/0063237 A1
(43) Pub. Date: Apr. 1, 2004

(54) Fabricating complex micro-electromechanical systems using a dummy handling substrate

(76) Inventors: Chang-Han Yun, Boston, MA (US); Lawrence E. Felton, Hopkinton, MA (US); Maurice S. Karpman, Brookline, MA (US); John A. Yasaitis, Lexington, MA (US); Michael W. Judy, Wakefield, MA (US); Colin Gormley, Belfast (IE)

Correspondence Address: BROMBERG & SUNSTEIN LLP, 125 SUMMER STREET, BOSTON, MA, 02110-1618, US

(21) Appl. No.: 10/259,174

(22) Filed: Sep. 27, 2002

(51) Int. Cl. H01L 21/00

(52) U.S. Cl. 438/48

(57) ABSTRACT

A dummy handling substrate is used to form complex micro-electromechanical systems. A two-sided micromachined structure is fabricated by forming micromachined structures on a front side of a wafer, bonding the front side of the wafer to a dummy handling substrate, and forming micromachined structures on a back side of the wafer using the dummy handling substrate to handle the wafer during this back side processing. A second wafer containing micromachined features may be bonded to the back side of the first wafer using the dummy handling substrate to handle the first wafer during this bonding. The dummy handling substrate is removed from the front side of the wafer after back side processing and/or bonding of the second wafer.

### FIELD OF THE INVENTION

The present invention relates generally to micro-electromechanical systems (MEMS), and more particularly to fabricating complex micro-electromechanical systems using a dummy handling substrate.

### BACKGROUND OF THE INVENTION

A micro-electromechanical system (MEMS) is a micromachined device that includes mechanical structures. MEMS devices can be such things as optical switching devices, accelerometers, and gyroscopes. In order to increase functionality of MEMS devices, it is desirable to integrate MEMS devices with integrated circuits (ICs) in a single chip. Such a chip is often referred to as an integrated MEMS.

Integrated MEMS devices are typically fabricated in a planar fashion on one side of a wafer substrate. Mechanical and electronic structures can be formed on the wafer in any of a variety of ways, including etching into the wafer and depositing materials onto the wafer. Because the mechanical and electronic structures are formed in a single plane with structures adjacent to one another, the integrated MEMS device can encompass a relatively large chip area. Also, because the mechanical and electronic structures are formed on a single wafer, the various processes used to form the mechanical and electronic structures must be compatible with one another (i.e., a particular process should not cause damage to structures formed by earlier processes).

### SUMMARY OF THE INVENTION

In accordance with one aspect of the invention, a dummy handling substrate is used to form complex micro-electromechanical systems. A two-sided micromachined structure is fabricated by forming micromachined structures on a front side of a wafer, bonding the front side of the wafer to a dummy handling substrate, and forming micromachined structures on a back side of the wafer using the dummy handling substrate to handle the wafer during this back side processing. A second wafer containing micromachined features may be bonded to the back side of the first wafer using the dummy handling substrate to handle the first wafer during this bonding. The dummy handling substrate is removed from the front side of the wafer after back side processing and/or bonding of the second wafer.

In accordance with another aspect of the invention, a method for fabricating a micro-electromechanical system involves providing a first micromachined apparatus having a front side including at least one micromachined structure, bonding a handling substrate to the front side of the first micromachined apparatus, and processing a back side of the first micromachined apparatus using the handling substrate to handle the first micromachined apparatus during back side processing. Bonding a handling substrate to a front side of a first micromachined apparatus typically involves applying a protective material to the front side of the first micromachined apparatus and applying an adhesive material between the protective material and the handling substrate. The protective material is typically a photoresist or photoresist-like material. Applying a protective material to the front side of the first micromachined apparatus may involve spin-coating the protective material onto the front side of the first micromachined substrate or depositing the protective material onto the front side of the first micromachined substrate. The adhesive material may be applied to either the protective layer or to the handling substrate. The adhesive material may be a thermoplastic epoxy material, a heat-releasable double-sided tape, or an ultraviolet-releasable double-sided tape. Processing a back side of the first micromachined apparatus using the handling substrate to handle the first micromachined apparatus during back side processing may involve thinning the back side of the first micromachined apparatus and/or forming at least one micromachined structure on the back side of the first micromachined apparatus. The first micromachined apparatus may include a silicon wafer, a polysilicon wafer, a silicon-on-insulator wafer, or a multiple stack silicon-on-insulator wafer. A second micromachined apparatus may be bonded to the back side of the first micromachined apparatus after processing the back side of the first micromachined apparatus. The second micromachined apparatus may be an integrated circuit wafer. The handling substrate is typically removed from the front side of the first micromachined apparatus after bonding the second micromachined apparatus to the back side of the first micromachined apparatus. Removing the handling substrate from the front side of the first micromachined apparatus typically involves releasing an adhesive material and removing a protective material and any residual adhesive material from the front side of the first micromachined apparatus. The front side of the first micromachined apparatus may be processed after removing the handling substrate.

In accordance with another aspect of the invention, an apparatus includes a first wafer having micromachined structures on both a front side and a back side and a second wafer having micromachined structures on at least a front side, wherein the front side of the second wafer is bonded to the back side of the first wafer.

In accordance with another aspect of the invention, a micro-electromechanical system is formed by the process of providing a first micromachined apparatus having a front side including at least one micromachined structure, bonding a handling substrate to the front side of the first micromachined apparatus, and processing a back side of the first micromachined apparatus using the handling substrate to handle the first micromachined apparatus during back side processing.

In accordance with another aspect of the invention, an integrated micro-electromechanical system is formed by the process of providing a first micromachined apparatus having a front side including at least one micromachined structure, bonding a handling substrate to the front side of the first micromachined apparatus, processing a back side of the first micromachined apparatus using the handling substrate to handle the first micromachined apparatus during back side processing, bonding a second micromachined apparatus to the back side of the first micromachined apparatus after processing the back side of the first micromachined apparatus, and removing the handling substrate from the front side of the first micromachined apparatus after bonding the second micromachined apparatus to the back side of the first micromachined apparatus.

An advantage of bonding the two wafers together in a stacked configuration is that the density of devices is increased for a given chip area.

An advantage of fabricating the two wafers separately and subsequently bonding them together is that fabrication and handling processes can be optimized for each wafer.

### BRIEF DESCRIPTION OF THE DRAWINGS

In the accompanying drawings:

FIG. 1 shows an exemplary MEMS wafer in accordance with an embodiment of the present invention;

FIG. 2 shows the MEMS wafer bonded to the dummy handling substrate in accordance with an embodiment of the present invention;

FIG. 3 shows the various structures following thinning of the MEMS wafer in accordance with an embodiment of the present invention;

FIG. 4 shows the various structures following back side processing in accordance with an embodiment of the present invention;

FIG. 5 shows the IC wafer bonded to the back side of the MEMS wafer in accordance with an embodiment of the present invention;

FIG. 6 shows the various structures after the dummy handling substrate has been removed in accordance with an embodiment of the present invention;

FIG. 7 shows the MEMS wafer with integrated circuitry fabricated on the front side of the MEMS wafer in accordance with an alternate embodiment of the present invention;

FIG. 8 shows the MEMS wafer after a photoresist material is applied over the integrated circuitry and the MEMS structures are patterned into the photoresist material in accordance with an alternate embodiment of the present invention;

FIG. 9 shows the dummy handling substrate bonded to the MEMS wafer using an adhesive layer in accordance with an alternate embodiment of the present invention;

FIG. 10 shows the various structures after grinding of the back side of the MEMS wafer in accordance with an alternate embodiment of the present invention;

FIG. 11 shows the various structures after back side etching of the MEMS wafer in accordance with an alternate embodiment of the present invention;

FIG. 12 shows the various structures after back side material deposition processing in accordance with an alternate embodiment of the present invention;

FIG. 13 shows the IC wafer bonded to the back side of the MEMS wafer in accordance with an alternate embodiment of the present invention;

FIG. 14 shows the MEMS wafer and the IC wafer after removal of the dummy handling substrate in accordance with an alternate embodiment of the present invention;

FIG. 15 shows the MEMS wafer and the IC wafer after front side etching of the MEMS structures in accordance with an alternate embodiment of the present invention; and

FIG. 16 shows the MEMS wafer and the IC wafer after removal of the photoresist material and front side material deposition processing in accordance with an alternate embodiment of the present invention.

### DETAILED DESCRIPTION OF A PREFERRED EMBODIMENT

In an embodiment of the present invention, micromachined structures are formed on both sides of a wafer (referred to hereinafter as a MEMS wafer) using a dummy handling substrate. After fabricating micromachined structures on a front side of the MEMS wafer (referred to hereinafter as “front side processing” of the MEMS wafer), the dummy handling substrate is bonded to the front side of the MEMS wafer, and a back side of the MEMS wafer is micromachined (referred to hereinafter as “back side processing” of the MEMS wafer) using the dummy handling substrate to handle the MEMS wafer during this back side processing. Forming micromachined structures on both sides of the MEMS wafer increases the density of devices for a given chip area.

Specifically, micromachined structures are formed on the front side of the MEMS wafer. The various micromachined structures may be fabricated using any of a variety of techniques, including various etching and material depositing techniques. The wafer may be any type of wafer, including a silicon, polysilicon, silicon-on-insulator (SOI), or multiple stack SOI wafer.

The dummy handling substrate is then bonded to the front side of the MEMS wafer. This typically involves applying a protective material to the front side of the MEMS wafer and applying an adhesive material between the protective material and the dummy handling substrate. The protective material is typically a photoresist or photoresist-like material that is spin-coated or deposited onto the front side of the MEMS wafer, although it should be noted that the present invention is in no way limited to any particular type of protective material or to any particular technique for applying the protective material to the front side of the MEMS wafer. The adhesive material is typically a releasable adhesive material, such as a heat-releasable thermoplastic epoxy, a heat-releasable double-sided tape, or an ultraviolet-releasable double-sided tape, that is applied to the protective material or to the dummy handling substrate, although it should be noted that the present invention is in no way limited to any particular type of adhesive material or to any particular technique for releasing the adhesive material. The dummy handling substrate is typically a “blank” wafer having no special machining. The dummy handling substrate is typically selected so as to be compatible with the wafer handling processes used for subsequent processing of the MEMS wafer after the dummy handling substrate is bonded to the front side of the MEMS wafer (described in detail below). Selection of the dummy handling substrate may also take into account the adhesive material used for bonding the dummy handling substrate to the front side of the MEMS wafer. For example, a substantially transparent dummy handling substrate may be used when an ultraviolet-releasable adhesive is used to bond the dummy handling substrate to the front side of the MEMS wafer bacause a substantially transparent dummy handling substrate allows ultraviolet light to reach and release the adhesive material so that the dummy handling substrate can be removed from the front side of the MEMS wafer, as discussed below.

After the dummy handling substrate is bonded to the front side of the MEMS wafer, the back side of the MEMS wafer is micromachined (referred to hereinafter as “back side processing” of the MEMS wafer) using the dummy handling substrate to handle the MEMS wafer during this back side processing. The back side processing of the MEMS wafer typically involves thinning the MEMS wafer to a predetermined thickness and forming various micromachined structures on the back side of the MEMS wafer.

The back side processing of the MEMS wafer typically involves thinning the back side of the MEMS wafer, for example, by grinding or etching the wafer to a desired thickness. A pre-formed etch-stop layer in the wafer, such as an insulation layer of an SOI wafer, may be used to control the thickness of the wafer during thinning. The back side processing typically also involves forming at least one micromachined structure on the back side of the MEMS wafer, for example, by etching features into the back side of the MEMS wafer or depositing material onto the back side of the MEMS wafer. A pre-formed etch-stop layer in the wafer, such as an insulation layer of an SOI wafer, may be used to control the formation of micromachined structures etched into the back side of the MEMS wafer. A multiple stack SOI wafer can be used in situations where multiple etch-stops are required (such as one etch-stop to control the thickness of the wafer during thinning and another etch-stop to control the depth of etches used to form micromachined structures in the back side of the MEMS wafer).

The micromachined structures formed on the MEMS wafer typically include various mechanical structures, electronic connections, and low-voltage electronics. For example, an optical MEMS wafer might include optical mirrors that are etched from the wafer and deposited with various materials (e.g., a diffusion barrier layer, a reflective gold layer, and an anti-static material layer), as well as various electronics and electronic interconnects. The MEMS wafer typically does not include high-voltage and other complex electronics, such as high-voltage MEMS driving electrodes, signal processors, and amplifiers. Rather, these external electronics typically reside on the chip to which the MEMS wafer is ultimately bonded.

In an embodiment of the present invention, the external electronics are fabricated on a separate wafer (referred to hereinafter as an IC wafer) that is bonded to the back side of the MEMS wafer using the dummy handling substrate to handle the MEMS wafer during this bonding process. These electronics may be fabricated on the IC wafer using any of a variety of techniques, including various etching and material depositing techniques. The electronics on the IC wafer are typically configured so as to align with various micromachined features that are fabricated on the back side of the MEMS wafer as described above. The IC wafer may be any type of wafer, including a silicon, polysilicon, silicon-on-insulator (SOI), or multiple stack SOI wafer. The IC wafer can be bonded to the back side of the MEMS wafer using any of a variety of bonding techniques, and the present invention is in no way limited to any particular bonding technique. Bonding the IC wafer to the back side of the MEMS wafer further increases the density of devices for a given chip area.

It should be noted that the MEMS wafer and the IC wafer may be fabricated from different types of wafers and/or different fabrication techniques for forming the various micromachined structures. This allows each wafer to be handled and processed separately using processes that are optimized for the particular wafer and types of structures to be formed on the wafer.

After the IC wafer is bonded to the back side of the MEMS wafer, the dummy handling substrate is removed from the front side of the MEMS wafer. This typically involves, among other things, releasing the adhesive material and removing the protective material (along with any residual adhesive material) from the front side of the MEMS wafer. The technique used to release the adhesive material depends on the type of adhesive material used to bond the dummy handling substrate to the front side of the first micromachined assembly. For example, heat is applied for a heat-releasable adhesive (such as a thermoplastic epoxy or heat-releasable double-sided tape), and ultraviolate light is applied for an ultraviolet-releasable adhesive (such as an ultraviolet-releasable double-sided tape). The technique used to remove the protective material depends on the type of protective material applied to the front side of the first micromachined assembly. For example, wet (chemicals) or dry (gas or plasma) etching can be used to remove the protective material (e.g., oxygen plasma ashing can be used to remove a photoresist protective material in a dry environment).

After the dummy handling substrate, the adhesive material, and the protective material are removed from the front side of the MEMS wafer, any of a variety of finishing processes can be done. The finishing processes may include additional processing on the front side of the MEMS wafer (e.g., additional etching to release fragile mechanical structures), calibration, and trimming, to name but a few.

In one exemplary embodiment of the present invention, an integrated MEMS device is formed by bonding a MEMS wafer to an IC wafer in a “stack” configuring using a dummy handling substrate. Specifically, the dummy handling substrate is bonded to the front side of a pre-fabricated MEMS wafer. The back side of the MEMS wafer is then thinned, and micromachined structures are formed on and in the thinned back side of the MEMS wafer. The IC wafer is then bonded to the back side of the MEMS wafer, and the dummy handling substrate is removed from the front side of the MEMS wafer.

More specifically, a layer of MEMS devices and some interconnected integrated circuitry is fabricated on the front side of the MEMS wafer. Because this layer will subsequently be bonded to the dummy handling substrate and therefore must withstand the bonding and releasing processes, the MEMS devices are typically fabricated only to a coarse degree in such a way that the sensitive MEMS devices can be “released” during final processing. The MEMS devices may be optical mirrors or other releasable structures. In order to facilitate this releasing process during the final processing, this layer typically sits on top of an etch-stop material (typically SiO2). In order to incorporate single crystal MEMS/IC devices on a SiO2 etch-stop, the MEMS wafer is typically a single or multiple stack SOI wafer.

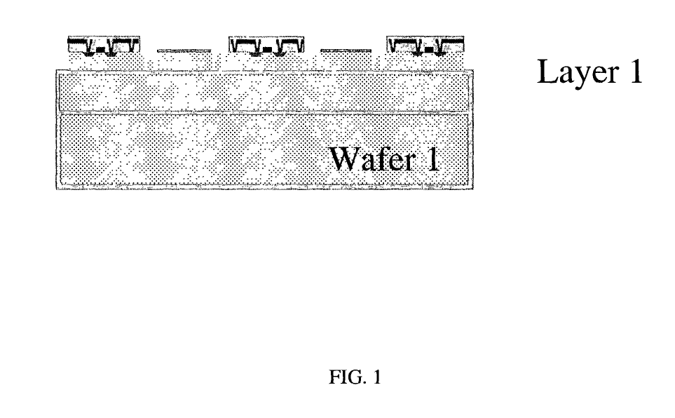

FIG. 1 shows an exemplary MEMS wafer in accordance with an embodiment of the present invention. The MEMS wafer (Wafer 1) is typically a single- or double-stack silicon-on-insulator (SOI) wafer on which is fabricated various IC devices and coarsely fabricated (patterned) MEMS devices (Layer 1). The MEMS devices may be mirrors or other releasable structures. In order to facilitate subsequent releasing of the releasable MEMS structures, the layer typically sits on to of an etch-stop layer. The etch-stop layer is typically silicon dioxide (SiO2).

After the front side of the MEMS wafer is fabricated (at least coarsely), the dummy handling substrate is bonded to the front side of the MEMS wafer. This typically involves applying a protective material over the layer of MEMS and IC devices on the MEMS wafer, applying an adhesive material over the protective material, and bonding the dummy handling substrate to the adhesive material. The primary purpose of the protective material is to protect the micromachined mechanical and electronic devices on the MEMS wafer from surface damage that can be caused by the adhesive layer.

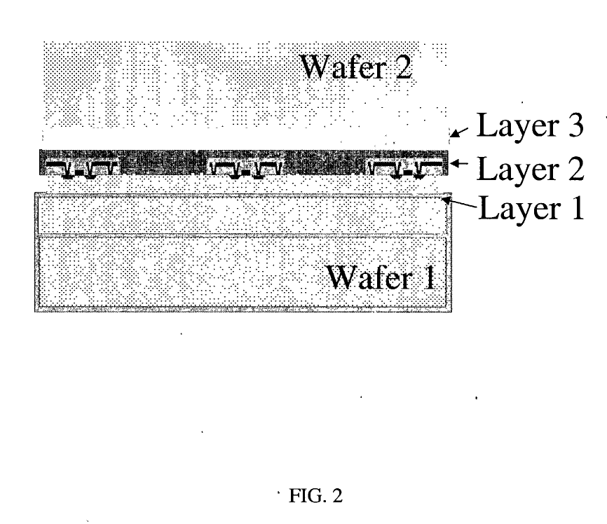

FIG. 2 shows the MEMS wafer bonded to the dummy handling substrate in accordance with an embodiment of the present invention. The protective material (Layer 2) is applied over the layer of coarsely fabricated MEMS and IC devices (Layer 1) on the front side of the MEMS wafer (Wafer 1), for example, using a spin-coating technique or by depositing a photoresist-like material. The adhesive material (Layer 3) is applied over the protective material (Layer 2). Some exemplary adhesive materials include thermoplastic epoxy, heat-releasable double-sided tape, and ultraviolet-releasable double-sided tape. The dummy handling substrate (Wafer 2) is bonded to the adhesive material (Layer 3). The dummy handling substrate (Wafer 2) can be any substrate, although it should be transparent when using an ultraviolet-releasable adhesive for Layer 3.

After the dummy handling substrate is bonded to the front side of the MEMS wafer, the MEMS wafer is typically thinned to a predetermined thickness. This can be done, for example, by grinding or etching the back side of the MEMS wafer to the predetermined thickness. One or more existing etch-stop layers in the MEMS wafer may be used to control the thickness of the MEMS wafer from the thinning process. When multiple etch-stops are required, multiple-stack SOI wafers can be used.

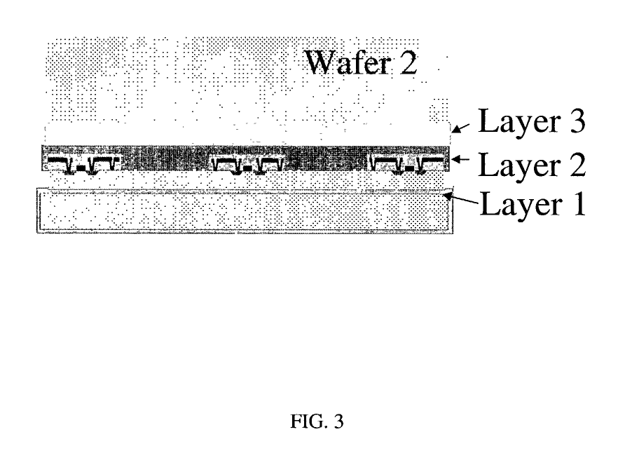

FIG. 3 shows the various structures following thinning of the MEMS wafer.

After the MEMS wafer is thinned, back side processing of the MEMS wafer is done. This can involve such things as back side etching to the MEMS devices, further selective etching to release the MEMS structure, and further processing to complete the back side of the MEMS devices, among other things.

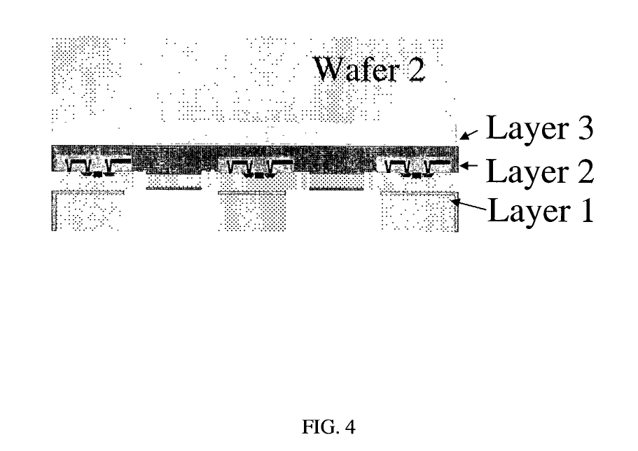

FIG. 4 shows the various structures following back side processing.

After thinning and back side processing, an IC wafer is bonded to the back side of the MEMS wafer, and electrical connections are made between the MEMS wafer and the IC wafer. The IC wafer typically includes various application-specific integrated circuits (ASIC) such as high voltage MEMS drive electronics, signal processors, and amplifiers, to name but a few. The electrical connections between the MEMS wafer and the IC wafer can be accomplished using a variety of techniques, including through-hole vias (e.g., through the MEMS wafer to the IC wafer) and wire bonding between the two wafers.

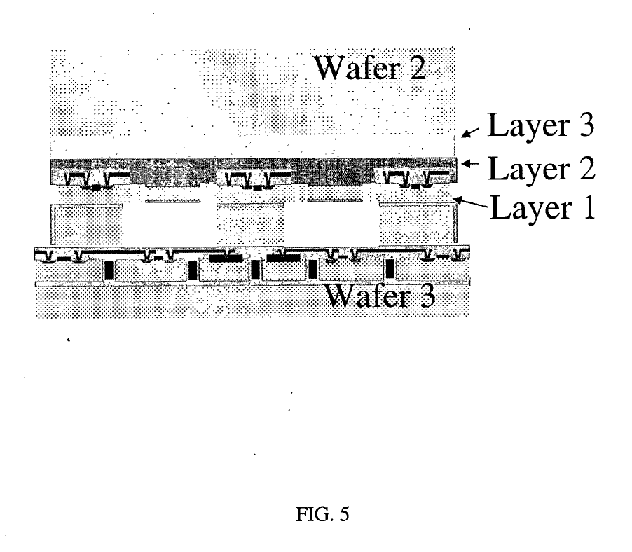

FIG. 5 shows the IC wafer (Wafer 3) bonded to the back side of the MEMS wafer.

After the IC wafer is bonded to the back side of the MEMS wafer, the dummy handling substrate is removed from the front side of the MEMS wafer. This typically involves, among other things, releasing the adhesive material (Layer 3) and removing the protective material (Layer 2). The adhesive material is typically removed using heat or ultraviolet light, depending on the type of adhesive. The protective material may be removed using wet (chemicals) or dry (gas or plasma) etching. For example, oxygen plasma ashing can be used to remove a photoresist material.

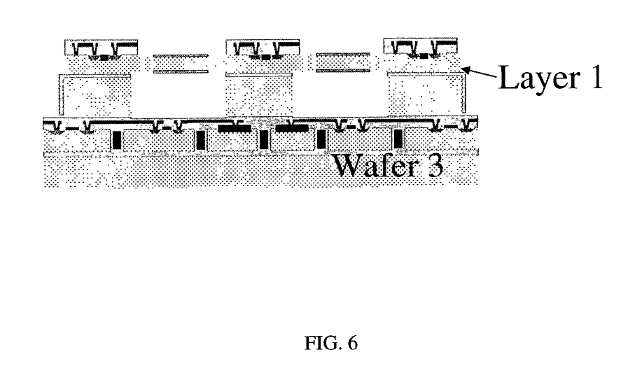

FIG. 6 shows the various structures after the dummy handling substrate has been removed.

After the dummy handling substrate has been removed, the MEMS and IC structures on the front side of the MEMS wafer (i.e., Layer 1) can be completed, and other finishing processes can be performed.

During back side processing of the MEMS wafer, channels may be formed through the MEMS/IC layer (Layer 1) to the protective layer (Layer 2). This exposes the protective material to any back side processes. Under some circumstances, the protective material can cause contamination during the back side processing. For example, if the protective material is an organic material (e.g., a photoresist material) and the back side processing uses a vacuum process (e.g., to deposit gold after etching), then the protective material can out-gas and cause contamination (e.g., of the gold or other material).

An alternate embodiment of the present invention prevents this contamination during back side processing by etching and finishing the MEMS structures after the dummy handling substrate has been removed. For example, after forming the integrated circuitry on the front side of the MEMS wafer, a photoresist (protective) material is applied over the integrated circuitry, for example, using a spin-coating technique. The MEMS structures are then patterned into the photoresist material, for example, using a lithograph process. The adhesive is then applied over the photoresist material, and the dummy handling substrate is bonded to the MEMS wafer. Any back side processing of the MEMS wafer is then performed, after which the IC wafer is bonded to the back side of the MEMS wafer and electrical connections are made between the MEMS wafer and the IC wafer. The dummy handling substrate is then removed from the front side of the MEMS wafer. The MEMS structures on the front side of the MEMS wafer are then etched and finished. Because there are no etches through the top layer of the MEMS wafer, the protective material does not become exposed during back side processing. Therefore, the protective material does not cause contamination during back side processing.

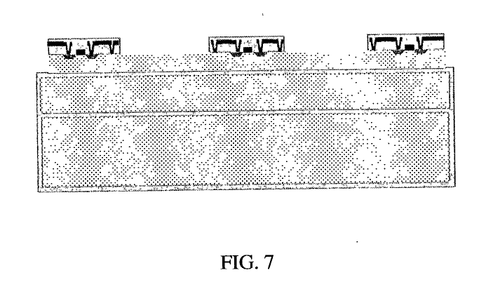

FIG. 7 shows the MEMS wafer with integrated circuitry fabricated on the front side of the MEMS wafer.

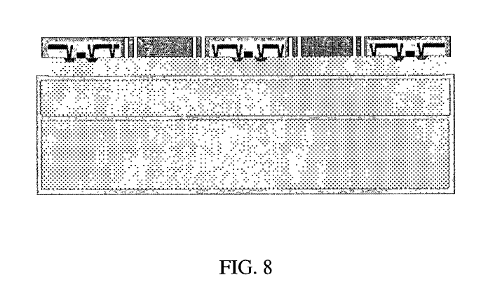

FIG. 8 shows the MEMS wafer after a photoresist material is applied over the integrated circuitry and the MEMS structures are patterned into the photoresist material.

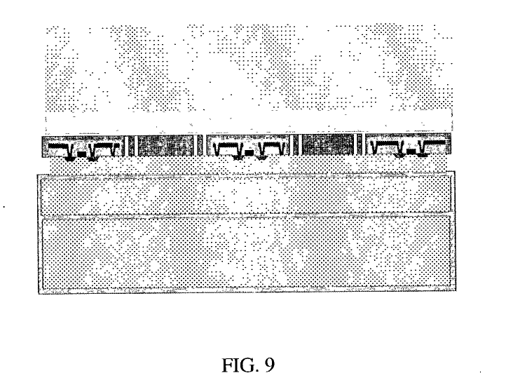

FIG. 9 shows the dummy handling substrate bonded to the MEMS wafer using an adhesive layer.

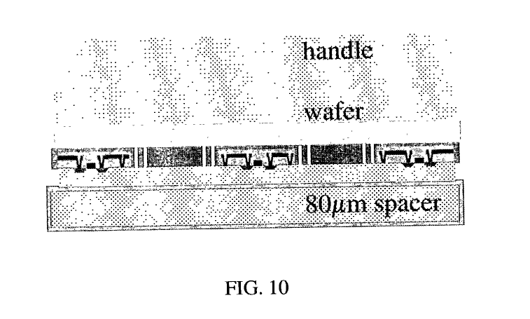

FIG. 10 shows the various structures after grinding of the back side of the MEMS wafer.

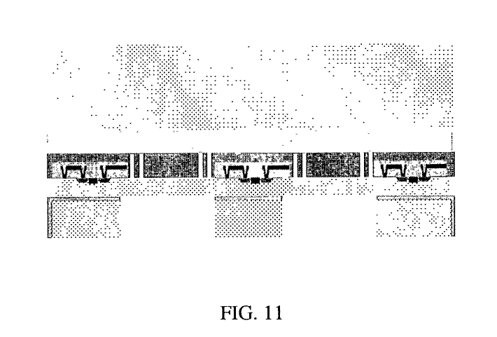

FIG. 11 shows the various structures after back side etching of the MEMS wafer.

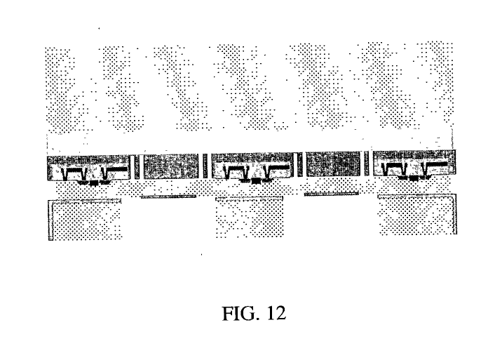

FIG. 12 shows the various structures after back side material deposition processing, such as shadow deposition of gold onto the back side of the MEMS mirrors.

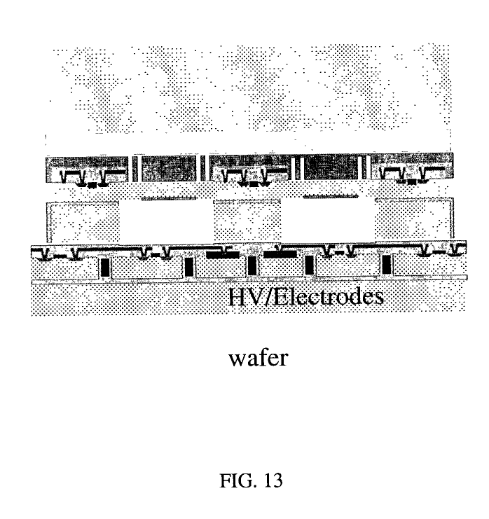

FIG. 13 shows the IC wafer bonded to the back side of the MEMS wafer.

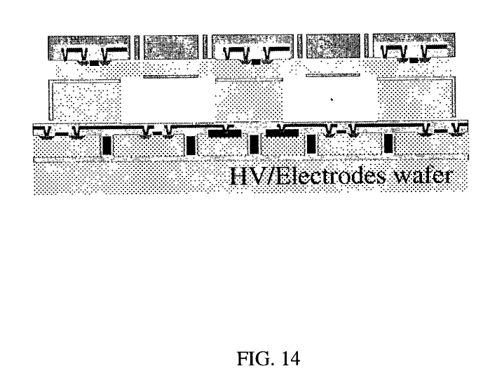

FIG. 14 shows the MEMS wafer and the IC wafer after removal of the dummy handling substrate.

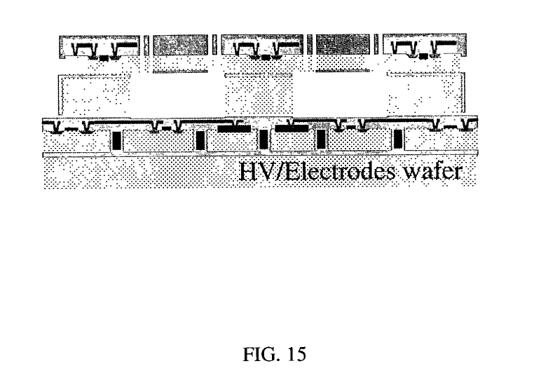

FIG. 15 shows the MEMS wafer and the IC wafer after front side etching of the MEMS structures.

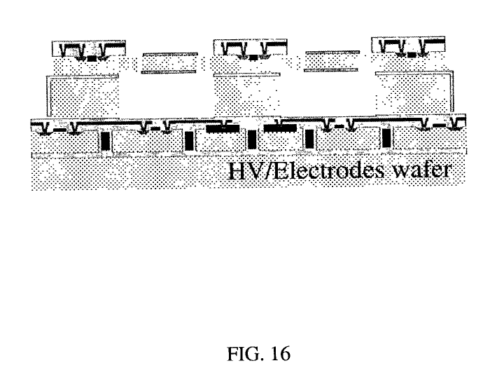

FIG. 16 shows the MEMS wafer and the IC wafer after removal of the photoresist material and front side material deposition processing, such as shadow deposition of gold onto the front side of the MEMS mirrors.

The following commonly-owned U.S. Patent Applications may be pertinent to the subject matter described herein, and are hereby incorporated herein by reference in their entireties:

U.S. patent application Ser. No. XX/XXX,XXX entitled FABRICATING COMPLEX MICRO-ELECTROMECHANICAL SYSTEMS USING A FLIP BONDING TECHNIQUE, filed on even date herewith in the names of Chang-Han Yun, Lawrence E. Felton, Maurice S. Karpman, John A. Yasaitis, Michael W. Judy, and Colin Gormley; and

U.S. patent application Ser. No. XX/XXX,XXX entitled FABRICATING INTEGRATED MICRO-ELECTROMECHANICAL SYSTEMS USING AN INTERMEDIATE ELECTRODE LAYER, filed on even date herewith in the names of Chang-Han Yun, Lawrence E. Felton, Maurice S. Karpman, John A. Yasaitis, Michael W. Judy, and Colin Gormley.

The present invention may be embodied in other specific forms without departing from the true scope of the invention. The described embodiments are to be considered in all respects only as illustrative and not restrictive.

What is claimed is:

1. A method for fabricating a micro-electromechanical system, the method comprising:
providing a first micromachined apparatus having a front side including at least one micromachined structure;
bonding a handling substrate to the front side of the first micromachined apparatus; and
processing a back side of the first micromachined apparatus using the handling substrate to handle the first micromachined apparatus during back side processing.

2. The method of claim 1, wherein bonding a handling substrate to a front side of a first micromachined apparatus comprises:
applying a protective material to the front side of the first micromachined apparatus; and
applying an adhesive material between the protective material and the handling substrate.

3. The method of claim 2, wherein the protective material comprises a photoresist or photoresist-like material.

4. The method of claim 2, wherein applying a protective material to the front side of the first micromachined apparatus comprises one of:
spin-coating the protective material onto the front side of the first micromachined substrate; and
depositing the protective material onto the front side of the first micromachined substrate.

5. The method of claim 2, wherein applying an adhesive material between the protective material and the handling substrate comprises one of:
applying the adhesive material to the protective layer; and
applying the adhesive material to the handling substrate.

6. The method of claim 2, wherein the adhesive material comprises one of:
a thermoplastic epoxy material;
a heat-releasable double-sided tape; and
an ultraviolet-releasable double-sided tape.

7. The method of claim 1, wherein processing a back side of the first micromachined apparatus using the handling substrate to handle the first micromachined apparatus during back side processing comprises at least one of:
thinning the back side of the first micromachined apparatus; and
forming at least one micromachined structure on the back side of the first micromachined apparatus.

8. The method of claim 1, wherein the first micromachined apparatus comprises one of:
a silicon wafer;
a polysilicon wafer;
a silicon-on-insulator wafer; and
a multiple stack silicon-on-insulator wafer.

9. The method of claim 1, further comprising:
bonding a second micromachined apparatus to the back side of the first micromachined apparatus after processing the back side of the first micromachined apparatus.

10. The method of claim 9, wherein the second micromachined apparatus comprises an integrated circuit wafer.

11. The method of claim 9, further comprising:
removing the handling substrate from the front side of the first micromachined apparatus after bonding the second micromachined apparatus to the back side of the first micromachined apparatus.

12. The method of claim 11, wherein removing the handling substrate from the front side of the first micromachined apparatus comprises:
releasing an adhesive material; and
removing a protective material and any residual adhesive material from the front side of the first micromachined apparatus.

13. The method of claim 11, further comprising:
processing the front side of the first micromachined apparatus after removing the handling substrate.

14. An apparatus comprising:
a first wafer having micromachined structures on both a front side and a back side; and
a second wafer having micromachined structures on at least a front side, wherein the front side of the second wafer is bonded to the back side of the first wafer.

15. A micro-electromechanical system formed by the process of:
providing a first micromachined apparatus having a front side including at least one micromachined structure;
bonding a handling substrate to the front side of the first micromachined apparatus; and
processing a back side of the first micromachined apparatus using the handling substrate to handle the first micromachined apparatus during back side processing.

16. An integrated micro-electromechanical system formed by the process of:
providing a first micromachined apparatus having a front side including at least one micromachined structure;
bonding a handling substrate to the front side of the first micromachined apparatus;
processing a back side of the first micromachined apparatus using the handling substrate to handle the first micromachined apparatus during back side processing;
bonding a second micromachined apparatus to the back side of the first micromachined apparatus after processing the back side of the first micromachined apparatus; and
removing the handling substrate from the front side of the first micromachined apparatus after bonding the second micromachined apparatus to the back side of the first micromachined apparatus.
